(19) United States
(12) Patent Application Publication
(10) Pub. No.: US 2026/0260842 A1
(43) Pub. Date: Sep. 3, 2026

(54) SEMICONDUCTOR CHARGED PARTICLE DETECTOR AND METHODS THEREOF

(71) Applicant: ASML Netherlands B.V., Veldhoven (NL)

(72) Inventors: Padmakumar RAMACHANDRA RAO, Veldhoven (NL); Sven JANSEN, Rijkevorsel (BE)

(21) Appl. No.: 18/873,382

(22) PCT Filed: Jul. 13, 2023
(86) PCT No.: PCT/EP2023/069554

§ 371 Date: Dec. 10, 2024

Related U.S. Application Data
(60) Provisional application No. 63/395,278, filed on Aug. 4, 2022.

(51) Int. Cl. H01J 37/244

(52) U.S. Cl. CPC H01J 37/244; H01J 2237/2441

(57) ABSTRACT

Systems and methods for charged particle detection using a charged particle detector in a charged-particle beam apparatus are disclosed. The apparatus may include a charged-particle detector comprising a substrate. The substrate may comprise a plurality of sensing elements configured to receive a plurality of charged particles generated from a sample. Each of the plurality of sensing elements comprises a first device configured to detect a charged particle of the plurality of charged particles having an energy equal to or below a first threshold and allow a charged particle of the plurality of charged particles having an energy greater than the first threshold to pass through. The sensing element further comprises a second device configured to detect the charged particle that is allowed to pass through the first device.

### CROSS-REFERENCE TO RELATED APPLICATIONS

This application claims priority of U.S. application 63/395,278 which was filed on Aug. 4, 2022 and which is incorporated herein in its entirety by reference.

### TECHNICAL FIELD

The description herein relates to particle detection, and more particularly, to systems and methods that may be applicable to particle detection with large dynamic range energy resolution.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the complexity in device architecture increases, accurate inspection of 3D structures, and the defects therein, has become more important.

Detectors may be used for sensing physically observable phenomena. For example, charged particle beam tools, such as electron microscopes, may comprise detectors that receive charged particles projected from a sample and that output a detection signal. Detection signals can be used to reconstruct images of sample structures under inspection and may be used, for example, to reveal defects in the sample. Detection of defects in a sample is increasingly important in the manufacturing of semiconductor devices, which may include large numbers of densely packed, miniaturized integrated circuit (IC) components. Dedicated inspection tools may be provided for this purpose. While charged particles such as secondary electrons or backscattered electrons may be individually detected with separate detectors having high efficiency, a single detector capable of detecting a wide range of energy of electrons may be desirable.

### SUMMARY

Embodiments of the present disclosure provide systems and methods for charged particle detection. One aspect of the present disclosure relates to a charged particle detector comprising a substrate. The substrate may comprise a plurality of sensing elements configured to receive a plurality of charged particles generated from a sample. Each of the plurality of sensing elements comprises a first device configured to detect a charged particle of the plurality of charged particles having an energy equal to or below a first threshold and allow a charged particle of the plurality of charged particles having an energy greater than the first threshold to pass through. The sensing element further comprises a second device configured to detect the charged particle that is allowed to pass through the first device.

Another aspect of the present disclosure relates to a charged-particle beam apparatus comprising a charged-particle source configured to emit charged particles forming a primary charged-particle beam and a charged-particle detector configured to detect a plurality of signal charged particles generated upon interaction of the charged particles of the primary charged-particle beam with a sample. The charged-particle detector may comprise a substrate. The substrate may comprise a plurality of sensing elements configured to receive a plurality of charged particles generated from a sample. Each of the plurality of sensing elements comprises a first device configured to detect a charged particle of the plurality of charged particles having an energy equal to or below a first threshold and allow a charged particle of the plurality of charged particles having an energy greater than the first threshold to pass through. The sensing element further comprises a second device configured to detect the charged particle that is allowed to pass through the first device.

Another aspect of the present disclosure relates to a method for charged particle detection using a substrate comprising a plurality of sensing elements configured to receive a plurality of charged particles generated from a sample. Each of the plurality of sensing elements comprising a first device and a second device. The method may include detecting, using the first device, a first charged particle of the plurality of charged particles having an energy equal to or below a first threshold, and detecting, using the second device, a second charged particle of the plurality of charged particles having an energy greater than the first threshold, after the second charged particle passes through the first device.

Another aspect of the disclosure relates to a non-transitory computer readable medium storing a set of instructions that is executable by one or more processors of a charged-particle beam apparatus comprising a charged-particle detector using a substrate comprising a plurality of sensing elements configured to receive a plurality of charged particles generated from a sample. Each of the plurality of sensing elements may comprise a first device and a second device, the set of instructions causing the charged-particle beam apparatus to perform a method. The method may include activating the first device to enable detection of a first charged particle of the plurality of charged particles having an energy equal to or below a first threshold, and activating the second device to enable detection of a second charged particle of the plurality of charged particles having an energy greater than the first threshold, after the second charged particle passes through the first device.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

FIG. 1 is a schematic diagram illustrating an exemplary electron beam inspection (EBI) system, consistent with embodiments of the present disclosure.

FIG. 2 is a schematic diagram illustrating an exemplary electron beam tool that can be a part of the exemplary electron beam inspection system of FIG. 1, consistent with embodiments of the present disclosure.

FIG. 3 illustrates a schematic diagram of an exemplary arrangement of a charged-particle detector configured to receive secondary charged particles from a sample, consistent with embodiments of the present disclosure.

FIG. 4 illustrates a schematic diagram of an exemplary charged-particle detector comprising sensing elements, consistent with embodiments of the present disclosure.

FIG. 5A illustrates a schematic diagram of a cross-sectional view of an exemplary sensing element of a charged-particle detector of FIG. 4, consistent with embodiments of the present disclosure.

FIG. 5B illustrates a schematic diagram of a cross-sectional view of an exemplary sensing element of a charged-particle detector of FIG. 4, consistent with embodiments of the present disclosure.

FIGS. 6A, 6B, 6C, and 6D illustrate various scenarios of discrimination of energy of incoming charged particle at a charged particle detector, consistent with embodiments of the present disclosure.

FIG. 7 illustrates a data plot of simulated response of an exemplary detection device to receiving and detecting charged particles such as electrons of a wide range of energy, consistent with embodiments of the present disclosure.

FIG. 8 is a process flowchart for an exemplary method of detecting charged particles, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC, thereby rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur.

In a SEM, interaction of electrons of a primary probing electron beam with a sample may generate secondary electrons, backscattered electrons, auger electrons, photons, x-rays, among other particles, which carry useful information about the sample. One of several ways to extract the sample information from the generated charged particles is to detect the charged particles and convert the information they carry into readable format such as images. The emission energy, or the energy of the charged particle exiting the sample, may be an indication of the emission depth and the type of interaction, and consequently, may be used to obtain information associated with the sample. As an example, low energy secondary electrons may interact with the top few nanometers of the sample surface, providing information about the topological features, surface morphology, etc., and higher energy backscattered electrons that are emitted from deeper regions of the interaction volume may provide information associated with chemical composition and bulk properties of the material. A large interaction volume of the primary electrons with the sample matter may generate charged particles having a wide range of energies from 1 eV to 100 eV or more, and in some cases, equal to the landing energy of the primary electrons. To maximize the extraction of useful information, it may be desirable to detect as many charged particles and as wide an energy range of the charged particles as possible.

Resolving or discriminating the energy level of a detected charged particle may allow accurate high-resolution imaging, accurate reconstruction of images from detected signals, among other advantages. One of several existing techniques to resolve energy levels and identify the incoming electrons on an electron detector such as a PIN diode, includes thresholding. One or more thresholds may be set to categorize the incoming charged particle based on its energy. For example, a first threshold at the lowest electron energy may be used to identify whether a sensing element has received an electron or if its output is caused by interference or dark current, or the like. The second threshold, with an intermediary electron energy, may be used to identify whether an electron received by a sensing element is a secondary electron from the sample or a backscattered electron from the sample. The third threshold, with the highest electron energy, may be used to identify whether a sensing element has received more than one electron. Thresholding, while being a useful technique to discriminate detected charged particles, may face limitations due to the narrow range of energy discrimination. For example, thresholding may be used to resolve energy levels between 10 eV to 20 eV, or between 5 eV to 10 eV, etc. However, for large dynamic ranges of energy such as from 1 eV to 100 eV or more, thresholding may be inadequate due to the low number of charge carriers generated by low energy electrons within the semiconductor substrate. One of several ways to detect low energy electrons may include using a single photon avalanche diode (SPAD) device, which may offer a high signal gain and high sensitivity. However, a SPAD device may face limitations in resolving higher electron energy simultaneously with the low electron energy. Therefore, it may be desirable to provide improved detection systems and methods capable of resolving a wide dynamic range of electron energy levels, while maintaining the inspection throughput, cost-efficiency, and easy operability.

Some aspects of the present disclosure may address some limitations by providing a charged particle detector comprising a SPAD and a PIN diode device. The charged particle detector may comprise an array of sensing elements and each sensing element may comprise a SPAD device, and a PIN diode device fabricated on the same substrate. The PIN diode device may be formed below the SPAD device with respect to the direction of the incidence of the incoming charged particle emitted from the sample. The SPAD device may be configured to detect charged particles having energy lower than a predetermined threshold while allowing the charged particles having energy higher than the threshold to pass through to be detected by the PIN device. The combination of SPAD and PIN device to resolve energy may enable a larger dynamic range discrimination. The SPAD device may further allow counting of arrival events of charged particles, timestamping or determining the time of arrival of a charged particle.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

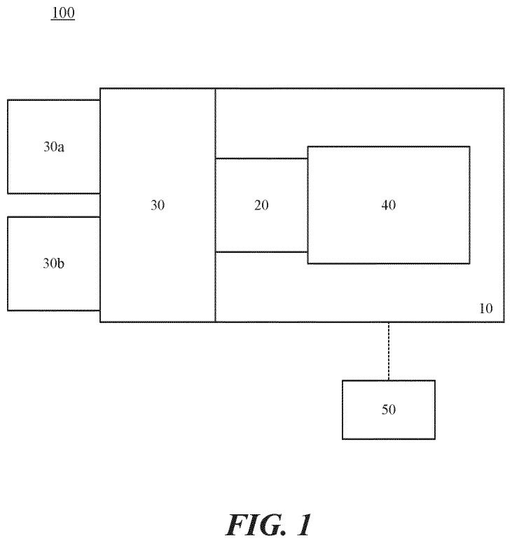

Reference is now made to FIG. 1, which illustrates an exemplary electron beam inspection (EBI) system 100 consistent with embodiments of the present disclosure. As shown in FIG. 1, charged particle beam inspection system 100 includes a main chamber 10, a load-lock chamber 20, an electron beam tool 40, and an equipment front end module (EFEM) 30. Electron beam tool 40 is located within main chamber 10. While the description and drawings are directed to an electron beam, it is appreciated that the embodiments are not used to limit the present disclosure to specific charged particles.

EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be inspected (wafers and samples are collectively referred to as “wafers” hereafter). One or more robot arms (not shown) in EFEM 30 transport the wafers to load-lock chamber 20.

Load-lock chamber 20 is connected to a load/lock vacuum pump system (not shown), which removes gas molecules in load-lock chamber 20 to reach a first pressure below the atmospheric pressure. After reaching the first pressure, one or more robot arms (not shown) transport the wafer from load-lock chamber 20 to main chamber 10. Main chamber 10 is connected to a main chamber vacuum pump system (not shown), which removes gas molecules in main chamber 10 to reach a second pressure below the first pressure. After reaching the second pressure, the wafer is subject to inspection by electron beam tool 40. In some embodiments, electron beam tool 40 may comprise a single-beam inspection tool. In other embodiments, electron beam tool 40 may comprise a multi-beam inspection tool.

Controller 50 may be electronically connected to electron beam tool 40 and may be electronically connected to other components as well. Controller 50 may be a computer configured to execute various controls of charged particle beam inspection system 100. Controller 50 may also include processing circuitry configured to execute various signal and image processing functions. While controller 50 is shown in FIG. 1 as being outside of the structure that includes main chamber 10, load-lock chamber 20, and EFEM 30, it is appreciated that controller 50 can be part of the structure.

While the present disclosure provides examples of main chamber 10 housing an electron beam inspection system, it should be noted that aspects of the disclosure in their broadest sense, are not limited to a chamber housing an electron beam inspection system. Rather, it is appreciated that the foregoing principles may be applied to other chambers as well.

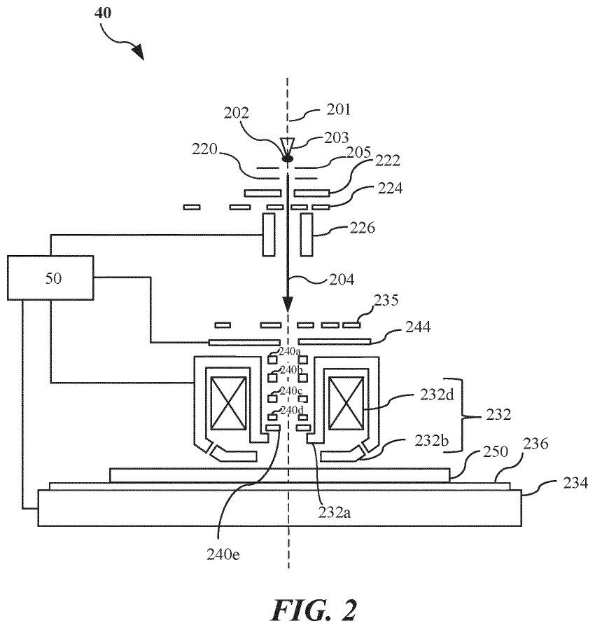

Reference is now made to FIG. 2, which illustrates a schematic diagram illustrating an exemplary configuration of electron beam tool 40 that can be a part of the exemplary charged particle beam inspection system 100 of FIG. 1, consistent with embodiments of the present disclosure. Electron beam tool 40 (also referred to herein as apparatus 40) may comprise an electron emitter, which may comprise a cathode 203, an extractor electrode 205, a gun aperture 220, and an anode 222. Electron beam tool 40 may further include a Coulomb aperture array 224, a condenser lens 226, a beam-limiting aperture array 235, an objective lens assembly 232, and an electron detector 244. Electron beam tool 40 may further include a sample holder 236 supported by motorized stage 234 to hold a sample 250 to be inspected. It is to be appreciated that other relevant components may be added or omitted, as needed.

In some embodiments, electron emitter may include cathode 203, an anode 222, wherein primary electrons can be emitted from the cathode and extracted or accelerated to form a primary electron beam 204 that forms a primary beam crossover 202. Primary electron beam 204 can be visualized as being emitted from primary beam crossover 202.

In some embodiments, the electron emitter, condenser lens 226, objective lens assembly 232, beam-limiting aperture array 235, and electron detector 244 may be aligned with a primary optical axis 201 of apparatus 40. In some embodiments, electron detector 244 may be placed off primary optical axis 201, along a secondary optical axis (not shown).

Objective lens assembly 232, in some embodiments, may comprise a modified swing objective retarding immersion lens (SORIL), which includes a pole piece 232a, a control electrode 232b, a beam manipulator assembly comprising deflectors 240a, 240b, 240d, and 240e, and an exciting coil 232d. In a general imaging process, primary electron beam 204 emanating from the tip of cathode 203 is accelerated by an accelerating voltage applied to anode 222. A portion of primary electron beam 204 passes through gun aperture 220, and an aperture of Coulomb aperture array 224, and is focused by condenser lens 226 so as to fully or partially pass through an aperture of beam-limiting aperture array 235. The electrons passing through the aperture of beam-limiting aperture array 235 may be focused to form a probe spot on the surface of sample 250 by the modified SORIL lens and deflected to scan the surface of sample 250 by one or more deflectors of the beam manipulator assembly. Secondary electrons emanated from the sample surface may be collected by electron detector 244 to form an image of the scanned area of interest.

In objective lens assembly 232, exciting coil 232d and pole piece 232a may generate a magnetic field. A part of sample 250 being scanned by primary electron beam 204 can be immersed in the magnetic field and can be electrically charged, which, in turn, creates an electric field. The electric field may reduce the energy of impinging primary electron beam 204 near and on the surface of sample 250. Control electrode 232b, being electrically isolated from pole piece 232a, may control, for example, an electric field above and on sample 250 to reduce aberrations of objective lens assembly 232 and control focusing situation of signal electron beams for high detection efficiency, or avoid arcing to protect sample. One or more deflectors of beam manipulator assembly may deflect primary electron beam 204 to facilitate beam scanning on sample 250. For example, in a scanning process, deflectors 240a, 240b, 240d, and 240e can be controlled to deflect primary electron beam 204, onto different locations of top surface of sample 250 at different time points, to provide data for image reconstruction for different parts of sample 250. It is noted that the order of 240a-e may be different in different embodiments.

Backscattered electrons (BSEs) and secondary electrons (SEs) can be emitted from the part of sample 250 upon receiving primary electron beam 204. A beam separator can direct the secondary or scattered electron beam(s), comprising backscattered and secondary electrons, to a sensor surface of electron detector 244. The detected secondary electron beams can form corresponding beam spots on the sensor surface of electron detector 244. Electron detector 244 can generate signals (e.g., voltages, currents) that represent the intensities of the received secondary electron beam spots, and provide the signals to a processing system, such as controller 50. The intensity of secondary or backscattered electron beams, and the resultant secondary electron beam spots, can vary according to the external or internal structure of sample 250. Moreover, as discussed above, primary electron beam 204 can be deflected onto different locations of the top surface of sample 250 to generate secondary or scattered electron beams (and the resultant beam spots) of different intensities. Therefore, by mapping the intensities of the secondary electron beam spots with the locations of sample 250, the processing system can reconstruct an image that reflects the internal or external structures of wafer sample 250.

In some embodiments, controller 50 may comprise an image processing system that includes an image acquirer (not shown) and a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detector 244 of apparatus 40 through a medium such as an electrical conductor, optical fiber cable, portable storage media, IR, Bluetooth, internet, wireless network, wireless radio, among others, or a combination thereof. In some embodiments, the image acquirer may receive a signal from electron detector 244 and may construct an image. The image acquirer may thus acquire images of regions of sample 250. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, controller 50 may include measurement circuitries (e.g., analog-to-digital converters) to obtain a distribution of the detected secondary electrons and backscattered electrons. The electron distribution data collected during a detection time window, in combination with corresponding scan path data of a primary beam 204 incident on the sample (e.g., a wafer) surface, can be used to reconstruct images of the wafer structures under inspection. The reconstructed images can be used to reveal various features of the internal or external structures of sample 250, and thereby can be used to reveal any defects that may exist in the wafer.

In some embodiments, controller 50 may control motorized stage 234 to move sample 250 during inspection. In some embodiments, controller 50 may enable motorized stage 234 to move sample 250 in a direction continuously at a constant speed. In other embodiments, controller 50 may enable motorized stage 234 to change the speed of the movement of sample 250 over time depending on the steps of scanning process.

As is commonly known, secondary electrons (SEs) may be identified as signal electrons with low emission energies, and backscattered electrons (BSEs) may be identified as signal electrons with high emission energies. The emission of SEs and BSEs obeys Lambert's law and has a large energy spread. SEs and BSEs are generated upon interaction of primary electron beam with the sample, from different depths of the sample and have different emission energies. For example, secondary electrons originate from the surface or near-surface, and may have an emission energy ≤50 eV, depending on the sample material, or volume of interaction, among other things. SEs are useful in providing information about surface features or surface geometries. BSEs, on the other hand, are generated by predominantly elastic scattering events of the incident electrons of the primary electron beam and generally have higher emission energies in comparison to SEs, in a range from 50 eV to approximately the landing energy of the incident electrons and provide compositional and contrast information of the material being inspected. The number of BSEs generated may depend on factors including, but are not limited to, atomic number of the material in the sample, acceleration voltage of primary electron beam, among other things.

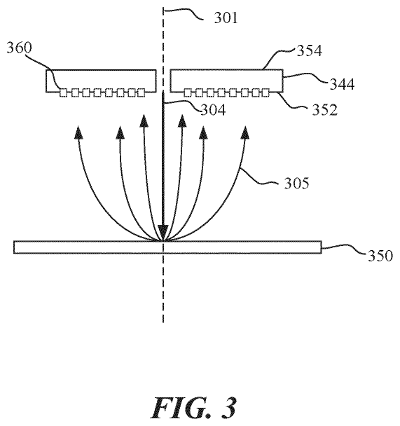

Reference is now made to FIG. 3, which illustrates a schematic diagram of an exemplary charged-particle detector configured to receive charged particles originating from a sample, consistent with some embodiments of the present disclosure. A primary charged-particle beam 304 along primary optical axis 301 may irradiate a region of sample 350, analogous to sample 250 of FIG. 2. Upon interaction with charged particles of primary charged-particle beam 304, sample 350 may generate one or more secondary charged-particle beams 305 comprising secondary charged particles such as, but not limited to, secondary electrons, backscattered electrons, photons, x-rays, auger electrons, among other charged particles. Charged-particle detector 344, analogous to charged-particle detector 244 of FIG. 2, may be placed upstream from sample 350. As used in the context of this disclosure, “upstream” refers to a position of an element located above or before another element, along the path of primary charged-particle beam (e.g., primary electron beam 204 of FIG. 2) starting from the electron source. It is to be appreciated that the charged-particle detectors, although not illustrated, may be configured to detect electrons, x-rays, photons, or any charged particle.

Charged-particle detector 344 may be provided as a detector plate having a front surface 352 and a rear surface 354, separated by a thickness of the detector plate. Rear surface 354 may be opposite the front surface 352. A “front” surface, as used herein, refers to a downstream horizontal surface facing the sample. As used in the context of this disclosure, “downstream” refers to a position of an element located below or after another element, along the path of primary charged-particle beam (e.g., primary electron beam 204 of FIG. 2) starting from the electron source. For example, front surface 352 of charged-particle detector 344 may be the downstream surface and rear surface 354 may be the upstream surface with respect to the path of the primary charged-particle beam 304 traveling along primary optical axis 301 towards sample 350.

As illustrated in FIG. 3, charged-particle detector 344 may comprise an array of sensing elements, including sensing element 360. The sensing elements may be arranged in a planar, two-dimensional array, the plane of the array being substantially perpendicular to an incidence direction of incoming charged particles. In some embodiments, charged-particle detector 344 may be arranged so as to be inclined at an angle relative to the incidence direction.

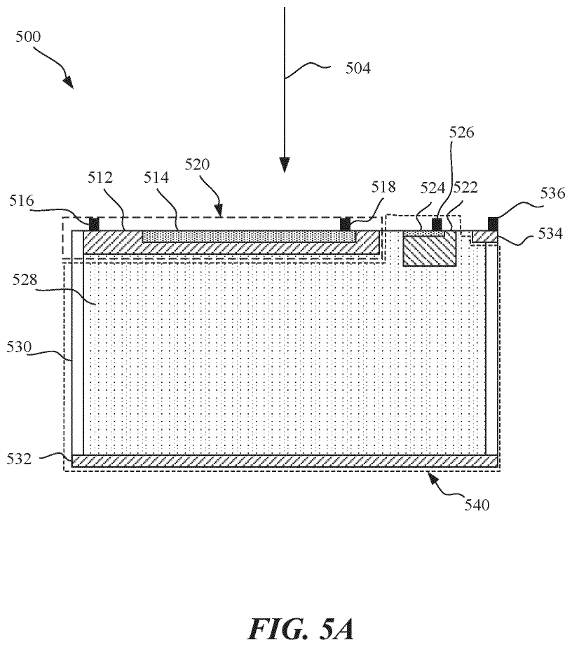

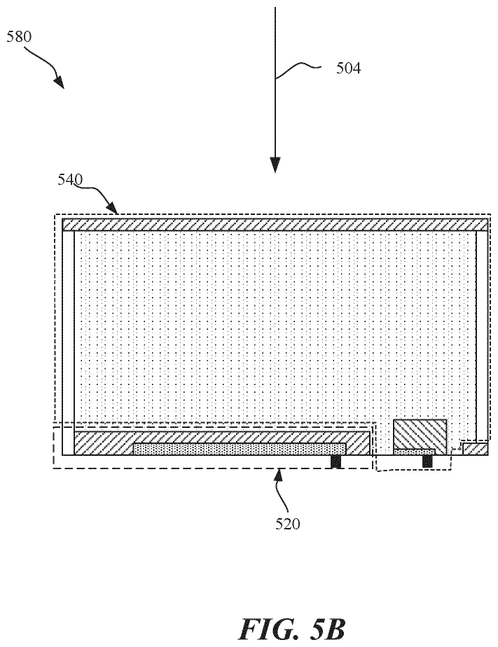

Charged-particle detector 344 may comprise a substrate including the array of sensing elements. In some embodiments, the substrate may comprise a semiconductor substrate. Sensing element 360 may comprise a semiconductor charged-particle detection device such as a photodiode, a PIN diode, a single photon avalanche photodiode (SPAD), a photomultiplier tube, an electron multiplier tube (EMT), or the like. In some embodiments, a semiconductor electron detector may be used in apparatus 40 in EBI system 100 of FIG. 1. EBI system 100 may be a high-speed wafer imaging SEM including an image processor. An electron beam generated by EBI system 100 may irradiate the surface of a sample or may penetrate the sample. EBI system 100 may be used to image a sample surface or structures under the surface, such as for analyzing layer alignment. In some embodiments, EBI system 100 may detect and report process defects relating to manufacturing semiconductor wafers by, for example, comparing SEM images against device layout patterns, or SEM images of identical patterns at other locations on the wafer under inspection. A semiconductor electron detector may comprise a semiconductor PIN diode that may operate with negative bias. A PIN diode may be configured so that incoming electrons generate a relatively large and distinct detection signal. In some embodiments, a PIN diode may be configured so that an incoming electron may generate a number of electron-hole pairs. A PIN diode, as referred to herein, may include a stacked configuration of p-type semiconductor (P), an intrinsic semiconductor (I), and an n-type semiconductor (N). In some embodiments, sensing element 360 may include a PIN diode, a single photon avalanche photodiode (SPAD), an electron multiplier tube (EMT), or combinations thereof. In some embodiments, sensing element 360 may comprise a combination of a PIN diode and SPAD fabricated on the same substrate, as discussed with reference to FIG. 5A.

In some embodiments, one or more sensing elements 360 may be fabricated on the substrate such that sensing element 360 is partially or substantially fully protruding from front surface 352. Alternatively, although not shown, one or more sensing elements may be fabricated such that they are substantially fully receding into the substrate of charged-particle detector 344.

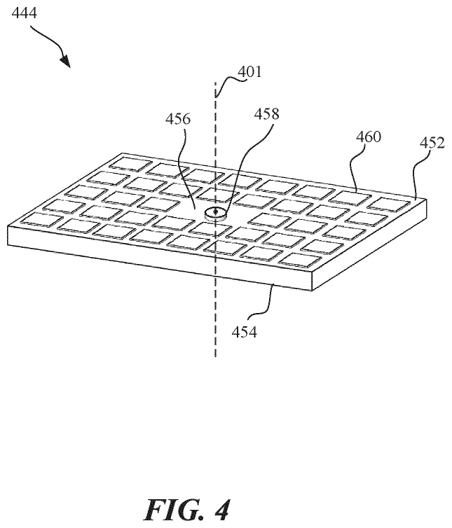

Reference is now made to FIG. 4, which illustrates a schematic diagram of an exemplary charged-particle detector 444, consistent with some embodiments of the present disclosure. Charged-particle detector 444 may be substantially similar to and may perform substantially similar functions as charged-particle detector 344 of FIG. 3. In some embodiments, charged-particle detector 444 may comprise an array of sensing elements, including sensing element 460 formed on surface 452. The sensing elements may be arranged in a planar, two-dimensional array such as, but not limited to, a rectangular array, a circular array, or other suitable arrangement. Charged-particle detector 444 may further include area 456 devoid of active components such as sensing elements. Area 456 may include an aperture or a through hole 458 to allow primary charged-particle beam (e.g., primary electron beam) to pass through. Charged-particle detector 444 may be placed such that the geometric centers of charged-particle detector 444 and aperture 458 substantially coincide with primary optical axis 401 along which the primary charged-particle beam (e.g., primary electron beam 204 of FIG. 2) travels.

Sensing elements may generate an electric signal commensurate with charged particles received in an active area of a sensing element. For example, a sensing element may generate an electric current signal commensurate with the energy of a received electron. A pre-processing circuit may convert the generated current signal into a voltage signal that may represent the intensity of an electron beam spot or a part thereof. The pre-processing circuitry may comprise, for example, pre-amp circuitries. Pre-amp circuitries may include, for example, a charge transfer amplifier (CTA), a transimpedance amplifier (TIA), or an impedance conversion circuit coupled with a CTA or a TIA. In some embodiments, signal processing circuitry may be included that provides an output signal in arbitrary units on a timewise basis. There may be provided one or a plurality of substrates, such as dies, that may form circuit layers for processing the output of sensing elements. The dies may be stacked together in a thickness direction of the charged-particle detector. Other circuitries may also be provided for other functions. For example, switch actuating circuitries may be provided that may control switching elements for connecting sensing elements to one another.

Reference is now made to FIG. 5A, which illustrates a cross-sectional view of an exemplary sensing element 500, consistent with embodiments of the present disclosure. Sensing element 500 may be an example of a sensing element 460 of FIG. 4 or sensing element 360 of FIG. 3. Sensing element 500 may comprise a substrate 528, which may be a semiconducting substrate such as, but not limited to, a silicon substrate. Substrate 528 may include a high resistivity semiconductor substrate with a doping density of 1×10¹² atoms/cm³ or less. A high resistivity substrate may be desirable as a fully depleted substrate layer and may contribute to the signal generated by a charge detection device such as a PIN diode. In some embodiments, substrate 528 may have a plurality of layers stacked in a direction substantially parallel to the incidence direction of a charged-particle beam such as a secondary electron beam 504. For example, substrate 528 may comprise one or more layers of doped semiconductor material, trenches, vias, or other structures.

In some embodiments, sensing element 500 of a charged-particle detector may comprise two or more charged-particle detection devices formed on a substrate. As shown in FIG. 5A, sensing element 500 may comprise a SPAD device 520 and a PIN diode device 540. SPAD device 520 and PIN diode device 540 may be fabricated on the same substrate 528 such that PIN diode device 540 abuts SPAD device 520 and is configured to receive charged particles that pass through SPAD device 520. It is to be appreciated that the broken lines marking the approximate boundaries of SPAD device 520 and PIN diode device 540 are visual aids for illustrative purposes only and do not represent the actual boundaries of the devices.

In some embodiments, SPAD device 520 may comprise a p-n junction device provided by a highly doped p⁺⁺ region 512 and a highly doped n⁺⁺ region 514. A highly doped region may include a p-dopant or a n-dopant in concentrations, for example, ranging from 10¹³ atoms/cm³ to 10¹⁸atoms/cm³. SPAD device 520 may further comprise contact pads 516 and 518 configured to make electrical connections to highly doped p-region 512 and highly doped n-region 514, respectively. Contact pads 516 and 518 may be configured to apply a voltage signal received from a control circuitry (e.g., controller 50 of FIG. 2) or measure a current signal based on the electron-hole pairs generated within the p-n junction of SPAD device 520. Contact pads 516 and 518 may be connected to external circuitry such as, but not limited to, signal processing circuitry, voltage control circuitry, timing circuitry, among other things. In some embodiments, although not shown, highly doped p⁺⁺ region 512 of SPAD device 520 may be electrically connected to another doped p-region 532 through a via (not illustrated) etched into substrate 528 and filled with an electrically conducting material such as, but not limited to, copper, titanium, tungsten, among other materials. In some embodiments, doped p-region 532 may form a contact bus line configured to form electrical connections with highly doped p⁺⁺ region 512 of multiple sensing elements of the array of sensing elements (e.g., array of sensing elements 460 of FIG. 4). Doped regions 512 or 532 of sensing element 500 may include a pure or almost pure amorphous boron layer as further described in U.S. Publication No. 2020/0212246, which is incorporated herein by reference in its entirety.

Sensing element 500 may further comprise PIN diode device 540 as a charged particle detector. PIN diode device 540 may include a p-region provided by high resistivity, lightly doped p-type substrate 528 and an n-region 522. Additionally, or alternatively, PIN diode device 540 may include a highly doped n⁺⁺ region 524 atop n-region 522 to facilitate electrical connection and minimize electrical resistance between contact 526 and n-region 522. A PIN diode, under reverse bias, may form a depletion region (not illustrated) or an intrinsic region devoid of charge carriers. In some embodiments, the depletion region may form and may span part of the length of p-type substrate 528 and part of the length of n-region 522. In the depletion region, charge carriers may be removed, and new charge carriers generated by incoming charged particles may be swept away according to their charge. For example, when an incoming charged particle arrives, electron-hole pairs may be created, and a hole may be attracted toward p-type substrate 528 while an electron may be attracted toward n-region 522, thereby forming a region depleted with charges.

In operation, a depletion region of a detection device may function as a capture region. An incoming charged particle may interact with the semiconductor material in the depletion region and generate new charges. For example, the detection device may be configured such that a charged particle having a certain amount of energy or greater may cause electrons of the lattice of the semiconductor material to be dislodged, thus creating electron-hole pairs. The resulting electrons and holes may be caused to travel in opposite directions due to, for example, an electric field in the depletion region. Generation of carriers that travel toward terminals of the sensing element may correspond to current flow in the detection device, thereby generating a measurable signal commensurate with the energy of the incoming charged particle.

Background noise in a detector may be caused by, among other things, dark current in a diode. For example, imperfections in a crystal structure of a semiconductor device acting as a diode may cause current fluctuation. Dark current in a detector may be due to defects in materials forming the detector and may arise even when there is no incident irradiation. “Dark” current may refer to the fact that current fluctuation is not related to any incoming charged particle. A diode may be configured to generate electron-hole pairs when a particle (e.g., a photon, or an electron) with no less than a certain level of energy enters the diode. For example, a photodiode may only generate an electron-hole pair when a photon with no less than a certain level of energy enters the photodiode. This may be due to, for example, the band gap of the materials that form the photodiode. A photon with energy equal to the certain level may be able to generate only one electron-hole pair, and even if a photon has more energy exceeding the certain level, it still may only generate one electron-hole pair. No additional electron-hole pairs may be generated. Meanwhile, an electron detector may be configured so that whenever an electron enters the depletion region of a detector device, which may include a diode, as long as the electron has energy of not less than a certain amount, e.g., approximately 3.6 eV, electron-hole pairs may begin to be generated. If the electron has more energy than the certain amount, more electron-hole pairs may be generated during the arrival event of the incoming electron.

In a diode configured for charged particle detection, defects in the diode may cause random generation of electron-hole pairs in the diode due to, for example, imperfections in a crystal lattice of a semiconductor structure. Dark current may be amplified by amplification effects, such as an avalanche amplification. The signal resulting from dark current may go on to be input into a counting circuit where it may be recorded as an arrival event. Such an event may be referred to as a “dark count,” which is an artifact and may contribute to false counts. Furthermore, amplifiers themselves may contribute to noise. Therefore, various sources of noise, such as dark current, thermal energy, extraneous radiation, etc., may cause unintended current fluctuations and inaccuracies in a detector's output.

One of several challenges associated with charge detection by an array of sensing elements in a charged particle detector (such as an electron detector in a SEM) may include crosstalk, caused by proximity between multiple sensing elements, defocused beams, among other factors. To mitigate the occurrence of crosstalk and its negative impact on signal fidelity, trenches 530 may be formed around a sensing element to isolate from the neighboring sensing elements. Trenches 530 may be filled with an electrically insulating material such as a dielectric including oxides, nitrides, oxynitrides, among other dielectrics. In some embodiments, trench 530 may be biased appropriately to act as a barrier for charges from neighboring sensing elements from influencing the output signal.

In a SEM, interaction of charged particles such as electrons of a primary probing electron beam with a sample may generate secondary electrons, backscattered electrons, auger electrons, photons, x-rays, among other charged particles. The emission energy of such generated charged particles may be in the range from 1 eV to the landing energy of the primary charged-particle beam. The emission energy may be an indication of the emission depth and the type of interaction, and consequently, may be used to obtain information associated with the sample. As an example, low energy secondary electrons may interact with the top few nanometers of the sample surface, providing information about the topological features, surface morphology, etc., and higher energy backscattered electrons that are emitted from deeper regions of the interaction volume may provide information associated with chemical composition and bulk properties of the material. Therefore, it may be desirable to detect signals having a wide range of emission energy to accurately reconstruct images of sample structures under inspection, thereby identifying and revealing defects in the sample.

One of several existing techniques to resolve energy levels and identify the incoming electrons on an electron detector includes thresholding. One or more thresholds may be set to categorize the incoming charged particle based on the energy of the charged particle. For example, a first threshold at the lowest electron energy may be used to identify whether a sensing element has received an electron or if its output is caused by interference or dark current, or the like. The second threshold, with an intermediary electron energy, may be used to identify whether an electron received by a sensing element is a secondary electron from the sample or a backscattered electron from the sample. The third threshold, with the highest electron energy, may be used to identify whether a sensing element has received more than one electron. While high electron energy levels may be resolved through thresholding, resolving a wide range of electron energy spanning from 1 eV to the landing energy of primary charged particles, may be challenging. This may be due to the low number of charge carriers generated by low energy electrons within the semiconductor substrate. One of several ways to detect low energy electrons may include using a SPAD device, which offers a high gain or signal amplification. A SPAD device may be reverse biased at a voltage exceeding the breakdown voltage of the diode, so that impact ionization may occur that causes an avalanche current to develop. However, a SPAD device may face limitations in resolving higher electron energy. Therefore, it may be desirable to resolve a wide dynamic range of electron energy levels for improved detection systems and methods, while maintaining the inspection throughput, cost-efficiency, and compact systems.

SPAD device 520 of sensing element 500 may be configured to detect low energy charged particles (e.g., low energy secondary electrons) while allowing high energy charged particles to pass through to be detected by PIN diode device 540, which abuts SPAD device 520. As illustrated in FIG. 5A, PIN diode device 540 may be formed immediately below SPAD device 520, with respect to the direction of the incoming charged particles in charged particle beam 504 that are generated from the sample. In some embodiments, SPAD device 520 and PIN diode device 540 may be fabricated on the same substrate, such as substrate 528. Semiconductor fabrication techniques such as, but not limited to, ion implantation, etching, photolithography, among other things, may be used to fabricate regions of SPAD device 520 and PIN diode device 540.

In operation, one or more secondary charged-particle beams (e.g., secondary charged-particle beams 305 of FIG. 3) may be incident on an array of sensing elements, configured to detect the charged particles and generate a corresponding signal, which may be processed to extract information associated with the detected charged particle. The low energy electrons may be detected by SPAD device 520 fabricated on a front surface (e.g., front surface 352 of FIG. 3) of sensing element 500, analogous to sensing element 360 of FIG. 3. SPAD device 520 may be reverse biased such that highly doped n⁺⁺ region 514 may be connected to a positive terminal of a power source (not illustrated) and highly doped p⁺⁺ region 512 may be connected to a negative terminal of the power source. A reverse bias applied to a SPAD device may form the depletion region around the p-n junction, which is depleted of charge carriers. SPAD device 520 may be reversed biased at a voltage higher than the breakdown voltage. A SPAD device operating at such high voltage regimes is referred to as operating in Geiger mode or counting mode. At this bias, the electric field is so high, typically higher than 10⁵ V/cm, that a single charge carrier injected in the depletion region may trigger an avalanche breakdown. Therefore, a SPAD device such as SPAD device 520 may be used to detect low energy electrons. In contrast, however, an avalanche photodiode (APD) may be operated at a reverse bias lower than the breakdown voltage and the signal amplification may not be as high as a SPAD device.

In some embodiments, SPAD device 520 may be configured to detect a charged particle having an energy below a threshold energy, Ths, and allow charged particles having energy higher than the threshold energy (Ths) to pass through. In some embodiments, the thickness of highly doped n⁺⁺ region 514, or of highly doped p⁺⁺ region 512, or both may be tailored to detect low energy charged particles. The thickness of individual layers or SPAD device 520 may determine the threshold energy Ths, above which the charged particle may escape the SPAD region and may enter the PIN diode region. As an example, the thickness of highly doped n⁺⁺ region 514 may be in a range from 0.1 to 1 μm, or 0.2 to 1 μm, or 0.3 to 1 μm, or 0.4 to 1 μm, or 0.5 to 1 μm, or 0.6 to 1 μm, or 0.7 to 1 μm, or 0.8 to 1 μm, or 0.9 to 1 μm. The thickness of highly doped p⁺⁺ region 512 may be in a range from 0.1 to 1 μm, or 0.2 to 1 μm, or 0.3 to 1 μm, or 0.4 to 1 μm, or 0.5 to 1 μm, or 0.6 to 1 μm, or 0.7 to 1 μm, or 0.8 to 1 μm, or 0.9 to 1 μm. It is to be appreciated that the thickness ranges listed herein are exemplary and may vary, as appropriate.

In some embodiments, the threshold energy Ths may be determined based on a doping concentration of highly doped n⁺⁺ region 514, or of highly doped p⁺⁺ region 512, or both. An intrinsic semiconductor such as Silicon (Si) may be doped with impurities to modify the electrical, optical, or structural properties. An exemplary dopant for a n-type semiconductor may comprise phosphorus, antimony, or bismuth, among other donor-type dopants. An exemplary dopant for a p-type semiconductor may include aluminum, gallium, or boron, among other acceptor-type dopants. The dopant concentration or doping density of highly doped n⁺⁺ region 514, or of highly doped p⁺⁺ region 512 may be 1×10¹³ atoms/cm³ or more, 1×10¹⁴ atoms/cm³ or more, 1×10¹⁵ atoms/cm³ or more, 1×10¹⁶ atoms/cm³ or more, 1×10¹⁷ atoms/cm³ or more, 1×10¹⁸ atoms/cm³ or more, or any suitable dopant concentration between 1×10¹³ atoms/cm³ and degenerate doping concentration.

In some embodiments, the threshold energy Ths may be determined based on a voltage applied to SPAD device 520, or electric field across the p-n junction of SPAD device 520. A voltage may be independently applied to highly doped n⁺⁺ region 514 or highly doped p⁺⁺ region 512 through contact pads 518 or 516, respectively. A controller (e.g., controller 50 of FIG. 2) may include circuitry configured to individually apply voltages to one or both regions of SPAD device 520. In some embodiments, SPAD device 520 and PIN diode device 540 may be independently enabled, disabled, or regulated, as desired.

In some embodiments, SPAD device 520 may be configured to perform charged particle counting, which may include determining individual charged particle arrival events occurring at a detector. For example, electrons may be detected one-by-one as they reach the detector. In some embodiments, electrons incident on a detector may generate an electrical signal that is routed to signal processing circuitries and then read-out to an interface, such as a digital controller. A detector may be configured to resolve signals generated by incident electrons and distinguish individual electrons with a discrete count. In some embodiments, information associated with particle counting may further be used to determine the time of arrival of a charged particle at the detector. In some embodiments, SPAD device 520 may be operated in Geiger-mode or counting mode to determine the number of charged particles detected by a detector. In Geiger-mode, for example, each incoming charged particle with high enough energy may generate one electron-hole pair. Then, due to internal impact ionization, this one pair may be multiplied by the avalanche gain so that several electron-hole pairs may eventually be generated. Thus, each incoming charged particle may result in several electron-hole pairs being generated. Due to strong internal electric field from high reverse bias voltage, the multiplication process may continue. Multiplication may be self-sustaining. When outside radiation disappears, current flow in the diode may not necessarily stop. Current in the diode may be stopped by disconnecting the diode from a power supply. After disconnection, current in the diode may then subside. Current output of a diode operated in the Geiger-mode may exhibit behavior including a long tail. For example, the output may gradually decrease after an initial peak. In the Geiger-mode, the diode may be provided with a quenching circuit. The quenching circuit may include a passive or an active quenching circuit. Actuating the quenching circuit may allow the diode to be shut down after each charged particle arrival event. Quenching may be used to reset a diode.

In some embodiments, the energy of a charged particle may be determined based on a characteristic of the current output signal of a detector. The characteristic may include time-over-threshold of the signal. For a given threshold energy level, the length of time that the current output of a diode is above the threshold energy, may be used to determine the energy of the incoming charged particle. A larger time-over-threshold value may indicate that the incoming charged particle has high energy. In contrast, a shorter time-over-threshold value may indicate that the incoming charged particle has lower energy.

A diode may be configured to operate with a level of gain. For example, a diode may be configured to operate with gain below 100. This may refer to a gain imparted by operation of the diode by application of voltage. The gain may amplify a signal up to, for example, 100 times relative to its original strength. It will be appreciated that other specific levels of gain may be used as well.

The use of a gain effect, such as that by a diode biased to avalanche mode or Geiger counting mode, may involve time-dependent phenomena. For example, a diode biased to avalanche mode may impart gain through avalanche multiplication. There may be a finite time associated with the gain effect. A diode may have a speed that is related to the time it takes for the gain effect to occur. In some situations, there may be a recovery time after an arrival event of a charged particle at the diode. A diode operated in Geiger counting mode may have an associated recovery time. Recovery time may limit the ability of a diode to detect discrete signals in close succession. A diode operated in Geiger counting mode may need to be quenched after a charged particle arrival event in order to accurately detect the next event.

Referring back to FIG. 5A, PIN diode device 540 may be configured to detect charged particles having energy higher than the threshold energy Ths, which are undetected by SPAD device 520. PIN diode device 540 may comprise p-type substrate 528, n-region 522, n⁺⁺ doped region 524. A p⁺⁺ doped layer may act as a common backside contact to provide electrical connection to one or more regions of sensing element 500.

A PIN diode may be used for charged particle (e.g., electron) counting. A PIN diode may have high natural internal gain, and thus, even in the case of a single electron arrival event, a strong, measurable signal may be generated that is easily distinguishable against a relatively low floor level of background noise. The need to provide an amplifier or complex systems on a chip, such as avalanche diodes, to boost the signal may be reduced or eliminated. Instead, a signal generated from a PIN diode by itself or with a relatively low-gain amplifier may be well suited for electron counting because it is generated quickly in response to an electron arrival event and may stand out against background noise. However, a single detector element including a PIN diode with one output may not be able to handle counting for all ranges of beam currents. For example, for a 1 nA electron beam, it is known that about 64 electrons may be incident on a detector in a typical 10 ns sampling period. In some SEM systems, a detector may run with a sampling rate of 100 MHz, thus corresponding to a 10 ns sampling period. In one sampling period of 10 ns, 64 electron arrival events may occur, and thus, signals generated from individual electron arrival events cannot be easily discriminated. Even in a high-speed detector, such as one running with a sampling rate of 800 MHz, there may be about 8 incident electrons per sampling period, which may overload the detector.

A PIN diode or a semiconductor diode having a PIN structure, may be operated in various modes. For example, in a first mode, the diode may be operated with normal reverse bias. In this mode, each incoming charged particle with high enough energy may generate only one electron-hole pair. When outside radiation (e.g., incoming charged particles) disappears, current flow in the diode may stop immediately. In a second mode, the diode may be operated with higher reverse bias than that in the first mode. The second mode may introduce impact ionization. This may also be referred to as avalanche photodiode mode. In this mode, each incoming charged particle with high enough energy may generate one electron-hole pair. Then, due to internal impact ionization, this one pair may be multiplied by avalanche gain so that several electron-hole pairs may eventually be generated. Thus, each incoming charged particle may result in several electron-hole pairs being generated. When outside radiation disappears, current flow in the diode may stop immediately. The second mode may include a linear region and a nonlinear region.

In some embodiments, PIN diode device 540 may be configured to have two or more levels of discrimination to resolve the incoming high energy charged particles. The two or more levels may be formed by using thresholds. Instead of or in addition to generating statistical results of received electron energy plotted against a number of electrons at each energy level, information may be generated with respect to the thresholds. Two or more thresholds may be set in a way that the high energy electrons may be further resolved. For example, the first threshold may discriminate charged particles having energy between a range of 10-20 eV, a second threshold may discriminate charged particles having energy between a range of 20-40 eV, and a third threshold may identify charged particles having energy higher than 40 eV. In some embodiments, the number of threshold levels may be determined based on the readout channel noise.

In some embodiments, sensing element 500 may comprise isolation regions or trenches 530 to provide isolation and prevent crosstalk between neighboring sensing elements of the array of sensing elements. Trenches 530 may be formed using semiconductor fabrication techniques commonly used for deep trench isolation structures to provide electrical isolation. In some embodiments, sensing element 500 may further include a sensing element separator 534, which may be used to regulate the electric field across trenches 530. A voltage may be applied to sensing element separator 534, through contact pad 536, to effectuate formation of an energy barrier for current to leak through or interfere with neighboring sensing elements.

In some embodiments, the ordering arrangement of SPAD device 520 and PIN diode device 540 may be reversed, as illustrated in a cross-sectional view of sensing element 580 in FIG. 5B. In such a configuration, low energy charged particles with sufficient energy may be detected by PIN diode device 540 and high energy charged particles may be detected by SPAD device 520. The threshold energy to detect high energy charged particles using SPAD device 520 may be determined based on the thickness of p-type substrate 528, among other things. A charged particle, to be detected by SPAD device 520, may have to have very high energy to travel through the thickness of substrate 528 before being incident on SPAD device 520. In some embodiments, the array of sensing elements of charged particle detector (e.g., charged particle detector 344 of FIG. 3) may comprise sensing element 500, or sensing element 580, or both.

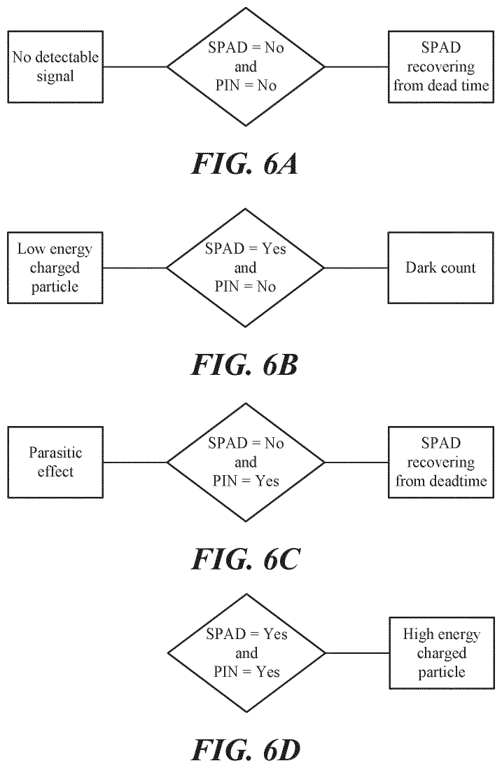

FIGS. 6A, 6B, 6C, and 6D illustrate various scenarios of discrimination of energy of incoming charged particle at a charged particle detector, consistent with embodiments of the present disclosure. In some embodiments, one or more external circuitries may be configured to process and generate an output based on the information received from a sensing element. For example, as shown in FIG. 6A, if both SPAD device 520 and PIN diode device 540 are not triggered, there may be two possible causes—either no detectable signals were received by sensing element 500 or SPAD device 520 may be recovering from dead time. In the context of this disclosure, “dead” time of a detector device refers to the time when an arriving charged particle may not be counted by the detector device. The dead time may be influenced by design or characteristics of an event detector or other characteristics such as a threshold level set for determining that an arrival event has occurred.

FIG. 6B illustrates a case in which SPAD device 520 may be triggered and PIN diode device 540 may not be triggered. In such a case, there may be two possible causes-either an arrival of a low energy charged particle was recorded or sensing element 500 counted a dark current (false positive signal). In a case where SPAD device 520 is not triggered but PIN diode device 540 presents an output, as shown in FIG. 6C, either SPAD device 520 may be recovering from dead time or there may be parasitic light effects causing the PIN diode device to present an output signal. If SPAD device 520 and PIN diode device 540 are both triggered, as shown in FIG. 6D, a high energy charged particle was received by PIN diode device 540.

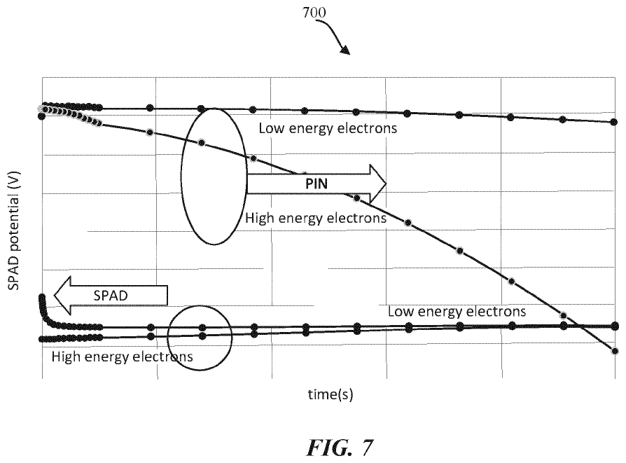

Reference is now made to FIG. 7, which illustrates a data graph 700 of simulation results obtained from an exemplary combined SPAD and PIN charged particle detector, consistent with embodiments of the present disclosure. A semiconductor simulator tool may be used to simulate the response of a combined SPAD and PIN diode detector when subjected to charged particles having a wide range of energy. The exemplary conditions for simulation include: depth of highly doped n⁺⁺ region=0.1-0.5 μm, depth of highly doped p⁺⁺ region=0.1-0.5 μm, depth of n-region=0.5-2.5 μm, spacing between SPAD region and n-region=1-5 μm, lightly doped p-type substrate, number of charges used for low energy charged particle simulation in the range of 1000-2000 electrons, and number of charges used for high energy charged particle simulation in the range of 2500-4000 electrons. The simulation was conducted for a signal detection of a short duration of several picoseconds. A high enough voltage bias was applied to SPAD device, ensuring the electric field was higher than the breakdown voltage of SPAD device to generate the avalanche breakdown, and an appropriate voltage of a few volts (V) was applied to PIN diode device.

As illustrated in the data graph 700, SPAD device instantaneously detects the incoming low energy electrons and PIN diode device detects the higher energy electrons. In the signal integration time of 0.1 ns, the high energy electrons do not get detected by SPAD device, instead they pass through and get detected by an underlying PIN diode device, as indicated by the drop in the potential of the PIN diode. The low energy electrons, on the other hand, are substantially detected in the SPAD region. It will be appreciated that a longer signal collection and integration time, in the order of several nanoseconds, would allow for more charges to be detected, thus improving the signal intensity.

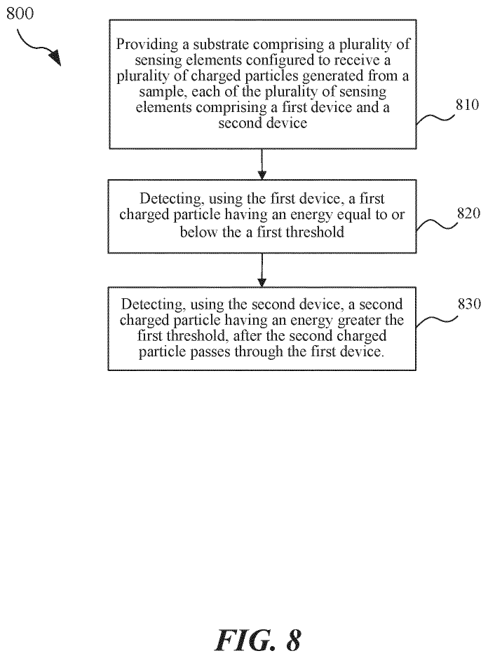

Reference is now made to FIG. 8, which illustrates a process flowchart representing an exemplary method 800 of detecting charged particles using a charged-particle detector, consistent with embodiments of the present disclosure. Method 800 may be used to detect a dynamic wide range of energy of charged particles using a charged particle detection device including a single photon avalanche diode (SPAD) and a PIN diode formed on the same substrate.

In step 810, a substrate comprising a plurality of sensing elements (e.g., sensing element 360 of FIG. 3 or sensing element 500 of FIG. 5A) may be provided. The sensing elements may be configured to receive charged particles generated from a sample upon interaction of a primary charged particle beam. Each of the sensing element may comprise a first charged particle detection device (e.g., SPAD device 520 of FIG. 5A) and a second charged particle detection device (e.g., PIN diode device 540 of FIG. 5A).

A charged-particle source is activated to emit charged particles. The charged particles may form a charged-particle beam (e.g., primary charged-particle beam 204 of FIG. 2). The electron source may be activated by a controller (e.g., controller 50 of FIG. 2). For example, the electron source may be controlled to emit primary electrons to form an electron beam along a primary optical axis (e.g., primary optical axis 201 of FIG. 2). The electron source may be activated remotely, for example, by using a software, an application, or a set of instructions for a processor of a controller to power the electron source through a control circuitry. The primary electron beam may pass through a Coulomb aperture array (e.g., Coulomb aperture array 224 of FIG. 2) and a beam-limit aperture array (e.g., beam-limit aperture array 305 of FIG. 3) to adjust the beam size or beam current of the primary electron beam and form a probing beam incident on the sample (e.g., sample 250 of FIG. 2).

In step 820, the first device (SPAD) is used to detect a charged particle (e.g., a secondary electron or a backscattered electron). The charged particle may have an energy equal to or below a first threshold, which may be a predetermined threshold energy level.

In step 830, the second device may be used to detect a second charged particle of the plurality of charged particles having an energy greater than the first threshold, after the second charged particle passes through the first device. The charged particle that passed through may have an energy higher than the first threshold and may comprise high energy electrons. The first device (SPAD) may enable charged particles having an energy higher than the first threshold to pass through towards the second device (PIN diode device). The PIN diode device is fabricated below the SPAD device, with respect to the direction of the incidence of the incoming charged particle from the sample.

A non-transitory computer readable medium may be provided that stores instructions for a processor of a controller (e.g., controller 50 of FIG. 1) to carry out image inspection, image acquisition, activating charged-particle source, irradiating a region of a sample with a primary charged particles, activating or disabling the charged particle detection devices individually, applying voltage to a charged particle detector, receiving and processing a signal generated by the charged particle detector in response to arrival of a charged particle, etc. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments of the present disclosure may further be described using the following clauses:

1. A charged-particle detector, comprising:
a substrate comprising a plurality of sensing elements configured to receive a plurality of charged particles generated from a sample, each of the plurality of sensing elements comprising:
a first device configured to:
detect a charged particle of the plurality of charged particles having an energy equal to or below a first threshold;
allow a charged particle of the plurality of charged particles having an energy greater than the first threshold to pass through; and
a second device configured to detect the charged particle that is allowed to pass through the first device.

2. The charged-particle detector of clause 1, wherein the first device is further configured to be operated at a reverse bias voltage higher than a breakdown voltage of the first device.

3. The charged-particle detector of any one of clauses 1 and 2, wherein the first device comprises a single photon avalanche diode (SPAD).

4. The charged-particle detector of clause 3, wherein the first device is further configured to operate in a Geiger-mode or a counting mode.

5. The charged-particle detector of any one of clauses 1-4, wherein the first threshold is dependent on a depth of the first device, the depth being equal to a sum of thicknesses of individual layers of the first device.

6. The charged-particle detector of any one of clauses 1-5, wherein the first threshold is dependent on a doping concentration of one or more layers of the first device.

7. The charged-particle detector of any one of clauses 1-6, wherein the first threshold is dependent on a voltage applied to the first device.

8. The charged-particle detector of any one of clauses 1-7, wherein in response to detection of the charged particle of the plurality of charged particles, the first device is configured to generate a first signal corresponding to a time of arrival of the charged particle.

9. The charged-particle detector of any one of clauses 1-8, wherein the second device is formed below the first device with respect to a path of an incoming charged particle.

10. The charged-particle detector of any one of clauses 1-9, wherein the second device comprises a PIN diode.

11. The charged-particle detector of any one of clauses 1-10, wherein in response to detection of the charged particle of the plurality of charged particles, the second device is configured to generate a second signal based on an energy of the detected charged particle.

12. The charged-particle detector of clause 11, wherein the energy of the detected charged particle is determined based on an amplitude of the generated signal.

13. The charged-particle detector of clause 12, wherein the energy of the detected charged particle is determined based on a duration of time that the amplitude of the generated signal is above a predetermined threshold energy.

14. The charged-particle detector of any one of clauses 11-13, wherein the energy of the charged particle detected by the second device is higher than the first threshold and lower than a second threshold.

15. The charged-particle detector of clause 13, wherein the energy of the charged particle detected by the second device is higher than the second threshold.

16. The charged-particle detector of clause 1, wherein the first device comprises a PIN diode.

17. The charged-particle detector of clause 16, wherein the first threshold is determined based on a depth of the first device.

18. The charged-particle detector of any one of clauses 16-17, wherein in response to detection of the charged particle of the plurality of charged particles, the first device is configured to generate a first signal based on an energy of the detected charged particle.

19. The charged-particle detector of any one of clauses 16-18, wherein the second device comprises single photon avalanche diode (SPAD).

20. The charged-particle detector of clause 19, wherein the SPAD is configured to be operated at a reverse bias voltage higher than a breakdown voltage of the first device.

21. The charged-particle detector of any one of clauses 19-20, wherein the SPAD is configured to operate in a Geiger-mode or a counting mode.

22. The charged-particle detector of any one of clauses 19-21, wherein the SPAD is formed below the first device with respect to a path of an incoming charged particle.

23. The charged-particle detector of any one of clauses 1-22, wherein the first and the second device are independently controlled by a controller having circuitry.

24. The charged-particle detector of any one of clauses 1-23, wherein a sensing element of the plurality of sensing elements is isolated from a neighboring sensing element.

25. A charged-particle beam apparatus, comprising:
charged-particle source configured to emit charged particles, the emitted charged particles forming a primary charged-particle beam; and
charged-particle detector configured to detect a plurality of signal charged particles generated upon interaction of the charged particles of the primary charged-particle beam with a sample, the charged-particle detector comprising:
a substrate comprising a plurality of sensing elements, each of the plurality of sensing elements comprising:
a first device configured to detect a charged particle of the plurality of charged particles having an energy equal to or below a first threshold energy and allow a charged particle of the plurality of charged particles having an energy greater than the first threshold energy to pass through; and
a second device configured to detect the charged particle that is allowed to pass through the first device.

26. The charged-particle beam apparatus of clause 25, wherein the first device is further configured to be operated at a reverse bias voltage higher than a breakdown voltage of the first device.

27. The charged-particle beam apparatus of any one of clauses 25 and 26, wherein the first device comprises a single photon avalanche diode (SPAD).

28. The charged-particle beam apparatus of clause 27, wherein the first device is further configured to operate in a Geiger-mode or a counting mode.

29. The charged-particle beam apparatus of any one of clauses 25-28, wherein the first threshold is dependent on a depth of the first device, the depth being equal to a sum of thicknesses of individual layers of the first device.

30. The charged-particle beam apparatus of any one of clauses 25-29, wherein the first threshold is dependent on a doping concentration of one or more layers of the first device.

31. The charged-particle beam apparatus of any one of clauses 25-30, wherein the first threshold is dependent on a voltage applied to the first device.

32. The charged-particle beam apparatus of any one of clauses 25-31, wherein in response to detection of the charged particle of the plurality of charged particles, the first device is configured to generate a first signal corresponding to a time of arrival of the charged particle.

33. The charged-particle beam apparatus of any one of clauses 25-32, wherein the second device is formed below the first device with respect to a path of an incoming charged particle.

34. The charged-particle beam apparatus of any one of clauses 25-33, wherein the second device comprises a PIN diode.

35. The charged-particle beam apparatus of any one of clauses 25-34, wherein in response to detection of the charged particle of the plurality of charged particles, the second device is configured to generate a second signal based on an energy of the detected charged particle.

36. The charged-particle beam apparatus of clause 35, wherein the energy of the detected charged particle is determined based on an amplitude of the generated signal.

37. The charged-particle beam apparatus of clause 36, wherein the energy of the detected charged particle is determined based on a duration of time that the amplitude of the generated signal is above a predetermined threshold energy.

38. The charged-particle beam apparatus of any one of clauses 35-37, wherein the energy of the charged particle detected by the second device is higher than the first threshold and lower than a second threshold.

39. The charged-particle beam apparatus of clause 37, wherein the energy of the charged particle detected by the second device is higher than the second threshold.

40. The charged-particle beam apparatus of clause 25, wherein the first device comprises a PIN diode.

41. The charged-particle beam apparatus of clause 40, wherein the first threshold is dependent on a depth of the first device.

42. The charged-particle beam apparatus of any one of clauses 40-41, wherein in response to detection of the charged particle of the plurality of charged particles, the first device is configured to generate a first signal based on an energy of the detected charged particle.

43. The charged-particle beam apparatus of any one of clauses 40-42, wherein the second device comprises a single photon avalanche diode (SPAD).

44. The charged-particle beam apparatus of clause 43, wherein the SPAD is configured to be operated at a reverse bias voltage higher than a breakdown voltage of the first device.

45. The charged-particle beam apparatus of any one of clauses 43-44, wherein the SPAD is configured to operate in a Geiger-mode or a counting mode.

46. The charged-particle beam apparatus of any one of clauses 43-45, wherein the SPAD is formed below the first device with respect to a path of an incoming charged particle.

47. The charged-particle beam apparatus of any one of clauses 25-46, wherein the first and the second device are independently controlled by a controller having circuitry.

48. The charged-particle beam apparatus of any one of clauses 25-47, wherein a sensing element of the plurality of sensing elements is isolated from a neighboring sensing element.

49. A method for charged particle detection using a substrate comprising a plurality of sensing elements configured to receive a plurality of charged particles generated from a sample, each of the plurality of sensing elements comprising a first device and a second device, the method comprising:
detecting, using the first device, a first charged particle of the plurality of charged particles having an energy equal to or below a first threshold; and
detecting, using the second device, a second charged particle of the plurality of charged particles having an energy greater than the first threshold, after the second charged particle passes through the first device.

50. The method of clause 49, further comprising operating the first device at a reverse bias voltage higher than a breakdown voltage of the first device.

51. The method of any one of clauses 49 and 50, wherein the first device comprises a single photon avalanche diode (SPAD).

52. The method of clause 51, wherein the first device is further configured to operate in a Geiger-mode or a counting mode.

53. The method of any one of clauses 49-52, wherein the first threshold is dependent on a depth of the first device, the depth being equal to a sum of thicknesses of individual layers of the first device.

54. The method of any one of clauses 49-53, wherein the first threshold is dependent on a doping concentration of one or more layers of the first device.

55. The method of any one of clauses 49-54, wherein the first threshold is dependent on a voltage applied to the first device.

56. The method of any one of clauses 49-55, wherein in response to detection of the charged particle of the plurality of charged particles, the first device is further configured to generate a first signal corresponding to a time of arrival of the charged particle.

57. The method of any one of clauses 49-56, wherein the second device is formed below the first device with respect to a path of an incoming charged particle.

58. The method of any one of clauses 49-57, wherein the second device comprises a PIN diode.

59. The method of any one of clauses 49-58, wherein in response to detection of the charged particle of the plurality of charged particles, the second device is configured to generate a second signal based on an energy of the detected charged particle.

60. The method of clause 59, wherein the energy of the detected charged particle is determined based on an amplitude of the generated signal.

61. The method of clause 60, wherein the energy of the detected charged particle is determined based on a duration of time that the amplitude of the generated signal is above a predetermined threshold energy.

62. The method of any one of clauses 59-61, wherein the energy of the charged particle detected by the second device is higher than the first threshold and lower than a second threshold.

63. The method of clause 61, wherein the energy of the charged particle detected by the second device is higher than the second threshold.

64. The method of clause 49, wherein the first device comprises a PIN diode.

65. The method of clause 64, wherein the first threshold is dependent on a depth of the first device.

66. The method of any one of clauses 64-65, wherein in response to detection of the charged particle of the plurality of charged particles, the first device is configured to generate a first signal based on an energy of the detected charged particle.

67. The method of any one of clauses 64-66, wherein the second device comprises a single photon avalanche diode (SPAD).

68. The method of clause 65, wherein the SPAD is configured to be operated at a reverse bias voltage higher than a breakdown voltage of the first device.

69. The method of any one of clauses 67-68, wherein the SPAD is configured to operate in a Geiger-mode or a counting mode.

70. The method of any one of clauses 67-69, wherein the SPAD is formed below the first device with respect to a path of an incoming charged particle.

71. The method of any one of clauses 49-70, wherein the first and the second device are independently controlled by a controller having circuitry.

72. The method of any one of clauses 49-71, wherein a sensing element of the plurality of sensing elements is isolated from a neighboring sensing element.

73. A non-transitory computer readable medium storing a set of instructions that is executable by one or more processors of a charged-particle beam apparatus comprising a charged-particle detector using a substrate comprising a plurality of sensing elements configured to receive a plurality of charged particles generated from a sample, each of the plurality of sensing elements comprising a first device and a second device, the set of instructions causing the charged-particle beam apparatus to perform a method, the method comprising:
activating the first device to enable detection of a first charged particle of the plurality of charged particles having an energy equal to or below a first threshold; and
activating the second device to enable detection of a second charged particle of the plurality of charged particles having an energy greater than the first threshold, after the second charged particle passes through the first device.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A charged-particle detector, comprising:
a substrate comprising a plurality of sensing elements configured to receive a plurality of charged particles generated from a sample, each of the plurality of sensing elements comprising:
a first device configured to:
detect a charged particle of the plurality of charged particles having an energy equal to or below a first threshold;
allow a charged particle of the plurality of charged particles having an energy greater than the first threshold to pass through; and
a second device configured to detect the charged particle that is allowed to pass through the first device.

2. The charged-particle detector of claim 1, wherein the first device is further configured to be operated at a reverse bias voltage higher than a breakdown voltage of the first device.

3. The charged-particle detector of claim 1, wherein the first device comprises a single photon avalanche diode (SPAD).

4. The charged-particle detector of claim 3, wherein the first device is further configured to operate in a Geiger-mode or a counting mode.

5. The charged-particle detector of claim 1, wherein the first threshold is dependent on a depth of the first device, the depth being equal to a sum of thicknesses of individual layers of the first device.

6. The charged-particle detector of claim 1, wherein the first threshold is dependent on a doping concentration of one or more layers of the first device.

7. The charged-particle detector of claim 1, wherein the first threshold is dependent on a voltage applied to the first device.

8. The charged-particle detector of claim 1, wherein in response to detection of the charged particle of the plurality of charged particles, the first device is configured to generate a first signal corresponding to a time of arrival of the charged particle.

9. The charged-particle detector of claim 1, wherein the second device is formed below the first device with respect to a path of an incoming charged particle.

10. The charged-particle detector of claim 1, wherein the second device comprises a PIN diode.

11. The charged-particle detector of claim 1, wherein in response to detection of the charged particle of the plurality of charged particles, the second device is configured to generate a second signal based on an energy of the detected charged particle.

12. The charged-particle detector of claim 11, wherein the energy of the detected charged particle is determined based on an amplitude of the generated second signal.

13. The charged-particle detector of claim 12, wherein the energy of the detected charged particle is determined based on a duration of time that the amplitude of the generated second signal is above a predetermined threshold energy.

14. The charged-particle detector of claim 11, wherein the energy of the charged particle detected by the second device is higher than the first threshold and lower than a second threshold.

15. A non-transitory computer readable medium storing a set of instructions that is executable by one or more processors of a charged-particle beam apparatus comprising a charged-particle detector using a substrate comprising a plurality of sensing elements configured to receive a plurality of charged particles generated from a sample, each of the plurality of sensing elements comprising a first device and a second device, the set of instructions causing the charged-particle beam apparatus to perform a method, the method comprising:
activating the first device to enable detection of a first charged particle of the plurality of charged particles having an energy equal to or below a first threshold; and
activating the second device to enable detection of a second charged particle of the plurality of charged particles having an energy greater than the first threshold, after the second charged particle passes through the first device.

16. The charged-particle detector of claim 1, wherein the first device comprises a PIN diode.

17. The charged-particle detector of claim 1, wherein the first threshold is determined based on a depth of the first device.

18. The charged-particle detector of claim 11, wherein in response to detection of the charged particle of the plurality of charged particles, the first device is configured to generate a first signal based on an energy of the detected charged particle.

19. The charged-particle detector of claim 1, wherein the second device comprises a single photon avalanche diode (SPAD).

20. A charged-particle beam apparatus, comprising:
a charged-particle source configured to emit charged particles, the emitted charged particles forming a primary charged-particle beam; and
a charged-particle detector configured to detect a plurality of signal charged particles generated upon interaction of the charged particles of the primary charged-particle beam with a sample, the charged-particle detector comprising:
a substrate comprising a plurality of sensing elements, each of the plurality of sensing elements comprising:
a first device configured to detect a charged particle of the plurality of charged particles having an energy equal to or below a first threshold energy and allow a charged particle of the plurality of charged particles having an energy greater than the first threshold energy to pass through; and
a second device configured to detect the charged particle that is allowed to pass through the first device.
